(19) United States
(12) Patent Application Publication
(10) Pub. No.: US 2007/0134567 A1
(43) Pub. Date: Jun. 14, 2007

(54) Mask and method of manufacturing display device using the same

(75) Inventors: Seung-kyu Park, Gyeonggi-do (KR); Jong-moo Huh, Gyeonggi-do (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/638,037

(22) Filed: Dec. 12, 2006

(30) Foreign Application Priority Data
Dec. 13, 2005 (KR) 2005-0122749

(51) Int. Cl. G03C 5/00; G03F 1/00

(52) U.S. Cl. 430/5; 430/394

(57) ABSTRACT

A mask for deposition of a low molecule deposition on a substrate for a display device comprises: a supporting frame formed with a pattern forming region; a plurality of pattern forming parts formed in the pattern forming region; and an auxiliary supporting frame formed between the pattern forming parts.

### CROSS-REFERENCE TO RELATED APPLICATIONS

This application claims the benefit of Korean Patent Application No. 2005-0122749, filed on Dec. 13, 2005, in the Korean Intellectual Property Office, the disclosure of which is incorporated herein by reference.

### FIELD OF THE INVENTION

The present invention relates to a mask and a method of manufacturing a display device using a mask for deposition of a low molecular weight material.

### DESCRIPTION OF THE RELATED ART

Organic light emitting diode (OLED) displays can be driven with a low voltage are thin and light, have a wide view angle and a relatively short response time. The OLED includes a plurality of organic layers such as a hole injecting layer and an emission layer emitting that can be formed by a deposition method using a shadow mask and a low molecule material; an inkjet printing method that drops an organic material through a nozzle; a coating method using a laser, etc. Among these methods, the low molecule deposition method has been most widely used. When the organic layer is formed by the low molecule deposition method, the shadow mask having an opening pattern is used to precisely deposit an emission material on a pixel electrode corresponding to the RGB pixels.

However, it is difficult to manufacture a shadow mask corresponding to a large-sized display apparatus and precisely align the opening pattern with the pixel electrode.

### SUMMARY OF THE INVENTION

In accordance with the present invention a mask comprises a supporting frame formed with a pattern forming region; a plurality of pattern forming parts formed in the pattern forming region; and an auxiliary supporting frame formed between the pattern forming parts. The pattern forming parts are spaced apart from each other by the length of one side of the square in four directions. The pattern forming parts may each comprise a stripe shape or a rectangular shape which are regularly spaced apart from each other. The pattern forming parts may comprise a plurality of openings adjacent to each other in one of a row direction and/or a column direction and spaced apart from each other by a predetermined distance in the other direction. According to an embodiment of the present invention, the pattern forming parts comprise openings that are randomly formed in an edge region thereof.

According to the embodiment of the present invention, the pattern forming parts comprise at least one pair of first and second opening patterns of which the openings are formed randomly and opposite to each other, and the openings are arranged regularly when the first and second opening patterns are overlapped.

According to the embodiment of the present invention, the pattern forming parts comprise two pairs of opening patterns of which the openings are formed randomly and opposite to each other, and the openings are arranged regularly when two pairs of opening patterns are overlapped.

According to the embodiment of the present invention, the pattern forming parts comprise four different corner opening patterns formed in the corners of the pattern forming parts and randomly formed with openings, and the openings are arranged regularly when the plurality of corner opening patterns are overlapped.

According to the embodiment of the present invention, the pattern forming parts comprise a pair of opening patterns of which the openings are randomly formed and which are formed in an edge of the pattern forming part, and the openings are arranged regularly when the pair of opening patterns are overlapped.

According to the embodiment of the present invention, the mask is interposed between an insulating substrate and an organic material, and allows the organic material to be deposited on a predetermined position of the insulating substrate.

According to the embodiment of the present invention, the pattern forming part protrudes with respect to the auxiliary supporting frame.

The foregoing and/or other aspects of the present invention can be achieved by providing a mask comprising: a supporting frame formed with a pattern forming region; a plurality of pattern forming parts formed in the pattern forming region and comprising openings formed randomly; and an auxiliary supporting frame formed between the pattern forming parts.

According to the embodiment of the present invention, the pattern forming part comprises at least one pair of first and second opening patterns which are opposite to each other, and the openings are arranged regularly when the first and second opening patterns are overlapped.

The foregoing and/or other aspects of the present invention can be achieved by providing a method of manufacturing a display device, comprising: preparing a substrate comprising a thin film transistor and a pixel electrode connected to the thin film transistor; attaching a mask to the substrate, the mask comprising a supporting frame formed with a pattern forming region, a plurality of pattern forming parts formed in the pattern forming region, and an auxiliary supporting frame formed between the pattern forming parts; depositing an emission material on the pixel electrode corresponding to the pattern forming part; moving the mask to dispose the pattern forming part on the pixel electrode corresponding to the auxiliary supporting frame; forming an emission layer with the emission material by repeating the deposition of the emission material and the movement of the mask.

According to the embodiment of the present invention, the manufacture of the mask comprises: forming the supporting frame and the auxiliary supporting frame as a single body; preparing a plurality of pattern forming units comprising the pattern forming part and a holder supporting the circumference of the pattern forming part; and welding the pattern forming unit to the auxiliary supporting frame while applying tension to the pattern forming part.

According to the embodiment of the present invention, the auxiliary supporting frame comprises a projection protruding upward corresponding to the holder, and the pattern forming unit is welded in the state that the holder is settled in the projection.

According to the embodiment of the present invention, the manufacture of the mask comprises: forming the supporting frame and the auxiliary supporting frame as a single body; preparing a rectangular frame formed with an opening corresponding to the pattern forming part, and welding the pattern forming part to the frame while applying tension to the pattern forming part; and coupling the frame with the supporting frame.

The foregoing and/or other aspects of the present invention can be achieved by providing a mask comprising: a supporting frame formed with a pattern forming region; a plurality of pattern forming parts formed in the pattern forming region; and an auxiliary supporting frame formed between the pattern forming parts and recessed with respect to the pattern forming part.

The foregoing and/or other aspects of the present invention can be achieved by providing a mask comprising: a supporting frame formed with a pattern forming region; an auxiliary supporting frame formed in the pattern forming region; and a pattern forming unit comprising a frame formed with an opening part, and a pattern forming part welded to the frame in correspondence with the opening part, wherein the pattern forming unit is coupled to the auxiliary supporting frame and provided detachably from the supporting frame.

### BRIEF DESCRIPTION OF THE DRAWING

The above and/or other aspects and advantages of the present invention will become apparent and more readily appreciated from the following description of the embodiments, taken in conjunction with the accompany drawings, in which:

FIGS. 1A and 1B show a mask according to a first embodiment of the present invention;

FIG. 2 shows a pattern forming region according to a second embodiment of the present invention;

FIG. 3 shows a pattern forming region according to a third embodiment of the present invention;

FIGS. 4A and 4B show a pattern forming part according to a fourth embodiment of the present invention;

FIG. 5 shows a pattern forming part according to a fifth embodiment of the present invention;

FIG. 6 shows a pattern forming part according to a sixth embodiment of the present invention;

FIGS. 7A and 7B shows a method of manufacturing the mask according to the first embodiment of the present invention; and

FIGS. 8A through 8C shows a method of manufacturing a display device according to a seventh embodiment of the present invention.

### DETAILED DESCRIPTION OF EMBODIMENTS

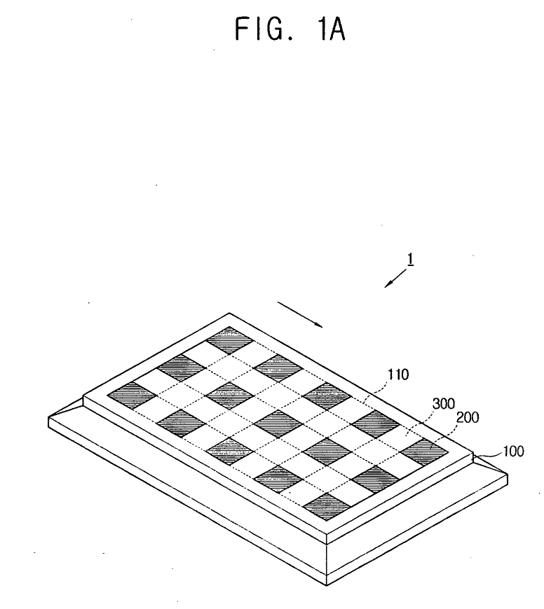

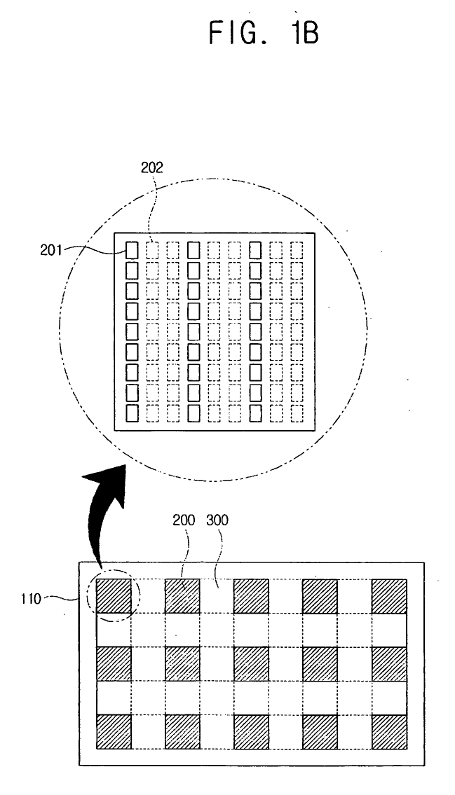

FIG. 1A is a perspective view of a mask according to a first embodiment of the present invention, and FIG. 1B illustrates a pattern forming region of the mask. Mask 1 according to the first embodiment of the present invention includes a supporting frame 100 having a pattern forming region 110; a plurality of pattern forming parts 200 provided in the pattern forming region 110; and an auxiliary supporting frame 300 provided between the pattern forming parts 200.

The supporting frame 100 has a rectangular shape, and is a little larger than a substrate on which an organic material such as an emission material is deposited. The supporting frame 100 surrounds and supports the pattern forming region 110.

In general, the supporting frame 100 is made of metal having high strength. The supporting frame 100 and the auxiliary supporting frame 300 are formed as a single body.

The pattern forming region 110 includes the plurality of pattern forming parts 200, and the auxiliary supporting frame 300 provided between the pattern forming parts 200. The pattern forming region 110 substantially contacts the substrate and has a size corresponding to the size of the substrate. Further, the pattern forming region 110 is surrounded with the supporting frame 100.

The pattern forming part 200 is formed with an opening pattern through which the organic material passes. The auxiliary supporting frame 300 formed between the pattern forming parts 200 supports the pattern forming parts 200 in four directions.

Conventionally, the opening pattern is formed throughout the pattern forming region, so that the conventional pattern forming part is equal to the pattern forming region. However, when the pattern forming part is equal to the pattern forming region, the size of the opening pattern is so large that it is difficult to precisely align the mask with a large-sized substrate. In general, the pattern forming part having the opening pattern is implemented by a thin metal film and welded on the supporting frame. The welding process for precisely disposing an opening on a pixel electrode of the substrate includes a process of expanding and settling the pattern forming part in four directions. The larger the size of the substrate is, the more the opening is not aligned with the pixel electrode while the pattern forming part is expanded and settled.

According to the present invention, the pattern forming parts 200 are formed not throughout the pattern forming region 110, but the auxiliary supporting frame 300 is partially formed in the pattern forming region 110. That is, the size of the pattern forming parts 200 requiring welding is reduced, thereby decreasing an aligning error between an opening 201 and the pixel electrode.

The pattern forming parts 200 are regularly arranged in the pattern forming region 110. In this embodiment, the pattern forming part 200 has a square shape. The pattern forming parts 200 are spaced apart from each other in four directions by the length of one side of the square. Here, the spaced part corresponds to the auxiliary supporting frame 300. The pattern forming part 200 and the auxiliary supporting frame 300 are arranged in a mesh pattern like a checkerboard.

The pattern forming part 200 includes an opening pattern of a known shadow mask. The shadow mask is provided between an insulating substrate and the organic material such as the emission material, and allows the organic material to be deposited at definite positions on the insulating substrate. Further, the shadow mask includes the openings arranged in regular. For example, the openings 201 are arranged in matrix. The openings 201 are formed to correspond to one per three pixel electrodes in a row direction, and to correspond to all pixel electrodes in a column direction. For convenience, a part having no opening 201 and corresponding to the pixel electrode will be defined as an imaginary dummy opening 202. In other words, the pattern forming part 200 includes a continuously repeated opening pattern of the opening 201 corresponding to one line and the dummy opening 202 corresponding to two lines in the column direction. However, the opening pattern is not limited to the above-described pattern, and may vary.

As described above, the pattern forming part 200 is implemented by forming the opening 201 on the metal film and welded to the auxiliary supporting frame 300. At this time, to align the opening 201 of the pattern forming part 200 with the pixel electrode, the metal film is welded to the auxiliary supporting frame 300 while applying a predetermined tension thereto in four directions, which is called tension welding.

Mask 1 can be made by directly welding the pattern forming part 200 to the supporting frame 100 formed integrally with the auxiliary supporting frame 300 or by welding the pattern forming part 200 to a separate frame and coupling the separate frame with the supporting frame 100. The manufacturing method for the mask 1 will be described later in more detail. When the organic layer such as an emission layer is formed on the substrate by using the mask 1 according to the present embodiment, the deposition must be perfomed twelve times and mask 1 must be moved nine times. The first deposition is performed while the pattern forming region 110 closely and precisely contacts the substrate. Then the second through fourth depositions are repeated while the mask 1 is sequentially moved in the arrow direction. That is, the emission material is deposited while the pattern forming part 200 moves to a part covered with the auxiliary supporting frame 300, thereby forming the emission layer corresponding to one color. Then, the mask 1 provided for the first deposition is moved by a distance corresponding to one pixel electrode, and the foregoing operation is repeated according to the emission materials. Thus, the emission layer corresponding to RGB is formed.

Alternatively, the pattern forming part 200 may have a rectangular shape instead of the square shape. In this case, the auxiliary supporting frame 300 provided between the pattern forming parts 200 are also shaped like the pattern forming part 200. That is, the pattern forming parts 200 are spaced apart from each other by the length of a long side in a direction of the long side and by the length of a short side in a direction of the short side. In even this case, the mask 1 should be moved three times to form one emission layer like the first embodiment.

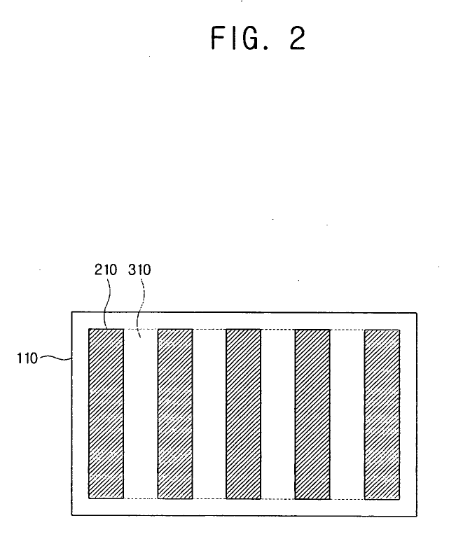

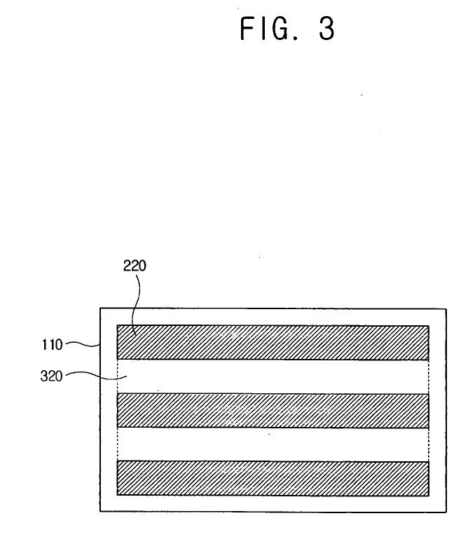

FIG. 2 shows a pattern forming region according to a second embodiment of the present invention, and FIG. 3 shows a pattern forming region according to a third embodiment of the present invention.

Referring to FIGS. 2 and 3, the pattern forming parts 210, 220 are shaped like a stripe. The pattern forming part 210 according to the second embodiment of the present invention has a stripe extended in a short side direction of the pattern forming region 110, and the pattern forming part 220 according to the third embodiment of the present invention has a stripe extended in a long side direction of the pattern forming region 110. Here, the width of the stripe is equal to the space between the pattern forming parts 210, 220. In other words, the width of the strip is equal to the width of the auxiliary support 310, 320 provided between the pattern forming parts 210 and 220.

When the mask according to the second embodiment is employed to deposit the emission material on the substrate, the mask is moved in the long side direction of the pattern forming region 110. On the other hand, when the mask according to the third embodiment is used to deposit the emission material on the substrate, the mask is moved in the short side direction of the patter forming region 110.

The pattern forming parts 210 and 220 according to the second and third embodiments require that the mask be moved once and the deposition be done twice to form one emission layer. Thus, the mask according to the second or third embodiment simplifies the process as compared with the process of using mask according to the first embodiment. Further, the mask according to the second and third embodiments reduces production cost.

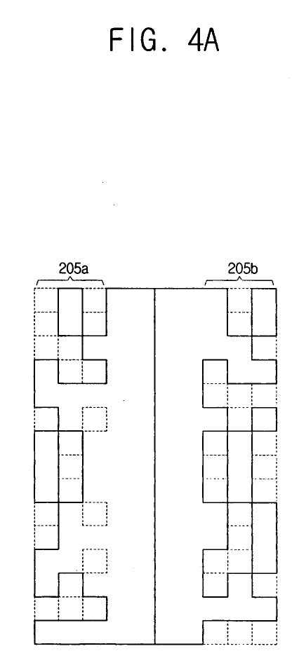

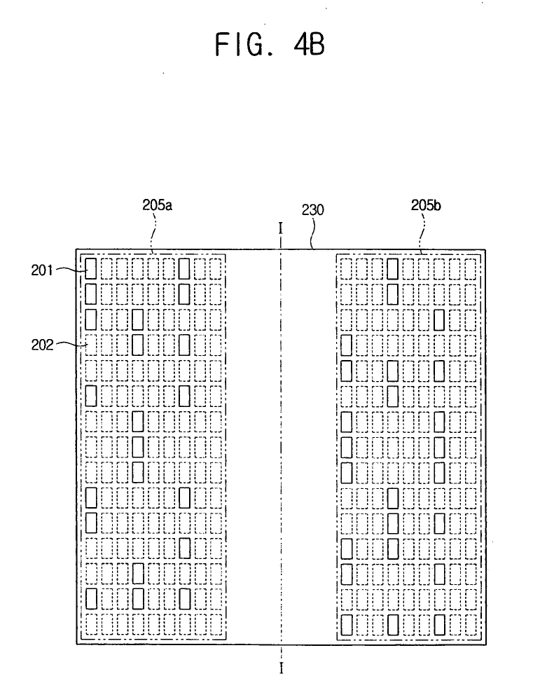

FIGS. 4A and 4B show a pattern forming part according to a fourth embodiment of the present invention. FIG. 4A illustrates a pattern forming part 230 including opening patterns 205 in opposite edges thereof, and FIG. 4B illustrates an opening 201 of the opening pattern 205.

The opening pattern 205 according to the fourth embodiment includes the opening 201 and the dummy opening 202 like the foregoing embodiments, but the openings 201 are arranged not in matrix but randomly. A pair of opening patterns 205a and 205b is formed in the opposite edges of the pattern forming part 230 and has the opening 201 and the dummy opening 202. Here, the opening 201 and the dummy opening 202 of the opening pattern 205a are the reverse to those of the opening pattern 205b. Therefore, when the first opening pattern 205a provided in the left side of the pattern forming part 230 is overlapped by the second opening pattern 205b provided in the right side of the pattern forming part 230, the total opening pattern has openings 201 that are regularly arranged in matrix.

When the masks according to the first through third embodiments are used in forming the emission layer on the substrate, the emission layer is not uniformly formed in a region adjacent to the pattern forming part because the masks should be moved. The non-uniform emission layer causes an image to have a stripe pattern when displayed on a display panel, thereby lowering the quality of the display device. To solve this problem, the openings are formed to be partially engaged in the region adjacent to the pattern forming part 230. That is, the openings 201 of the opposite edges of one pattern forming part 230 are not arranged in a straight line but engaged in a predetermined region when the pattern forming part 230 is moved.

Thus, the opening 201 do not have a straight boundary, so that the emission layer can be improved in uniformity even though the mask is moved, thereby decreasing the stripe pattern of an image displayed on the display panel.

In the fourth embodiment, the pattern forming part 230 can be obtained by varying the pattern forming part 210 having the stripe shape according to the second embodiment. That is, the pattern forming part 230 extended in the short side direction of the pattern forming region moves in the long side direction. Therefore, the openings 201 are randomly formed in an overlapped part while moving in the long side direction of the pattern forming region, i.e., in an edge of along side of the pattern forming part 230. Likewise, when the pair of opening patterns 205a and 205b formed in the edge are overlapped, the openings 201 are regularly arranged.

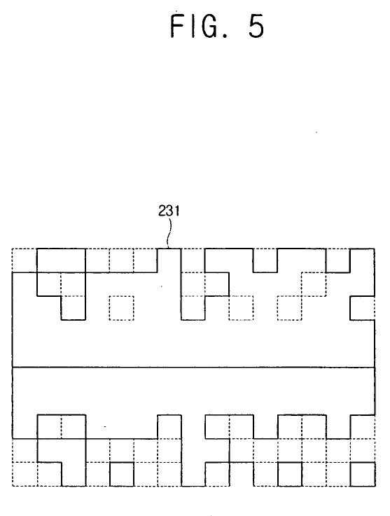

FIG. 5 shows a pattern forming part according to a fifth embodiment of the present invention, in which a pattern forming part 231 includes the openings randomly formed in the edge of the pattern forming part 230 according to the third embodiment. The pattern forming part 231 extended in the long side direction of the pattern forming region moves in the short side direction of the pattern forming region. Therefore, the openings are randomly formed in an overlapped part while moving in the short side direction of the pattern forming region, i.e., in an edge of a long side of the pattern forming part 231. Likewise, when the pair of opening patterns formed in the edge are overlapped, the openings are regularly arranged.

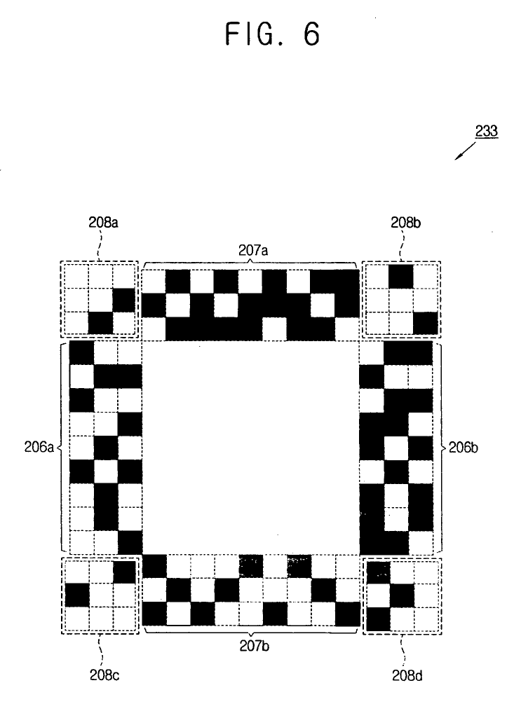

FIG. 6 shows a pattern forming part according to a sixth embodiment of the present invention. In this embodiment, a pattern forming part 233 includes openings randomly formed in all edges of the pattern forming part 200 according to the first embodiment.

The pattern forming part 233 includes two pairs of opening patterns 206a, 206b, 207a and 207b formed in opposite edges thereof, and four corner opening patterns 208a, 208b, 208c and 208d formed in corners thereof.

To deposit the organic material, the pattern forming part 233 according to the present embodiment moves up, down, left and right, total four times. Here, the first opening patterns 206a and 206b overlapped while moving left and right are similar to the opening pattern 205 of the fourth embodiment, and the second opening patterns 207a and 207b overlapped while moving up and down are similar to the opening pattern of the fifth embodiment.

According to the sixth embodiment, the pattern forming part 233 includes the corner opening patterns 208a, 208b, 208c and 208d formed in four vertexes thereof. When four opening patterns 208a, 208b, 208c and 208d are all overlapped, the openings are regularly arranged in matrix. As the pattern forming part 233 moves, the corners are overlapped totally four times, so that the openings formed in each corner opening pattern 208a, 208b, 208c and 208d should be not duplicated. That is, the openings should be designed to deposit the organic material totally once through each of four opening patterns 208a, 208b, 208c and 208d.

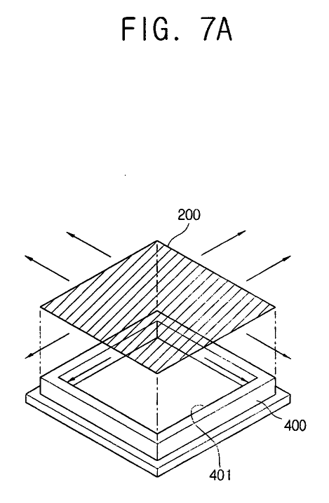

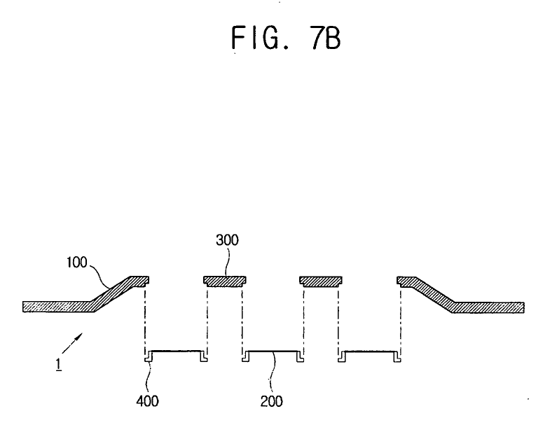

FIGS. 7A and 7B show a method of manufacturing the mask according to the first embodiment of the present invention, wherein FIG. 7A illustrates that the pattern forming part 200 is welded to a frame 400, and FIG. 7B illustrates that the frame 400 welded with the pattern forming part 200 is settled between the auxiliary supports 300. As shown in FIG. 7A, in the mask 1 according to this embodiment, the pattern forming part 200 is individually welded to the frame 400. Here, while tension is applied to the pattern forming part 200 in four directions, the welding is performed by a laser, which is called laser welding. Further, the frame 400 is implemented by a rectangular metal formed with an opening part 401 corresponding to the pattern forming part 200.

In the entire mask 1, the plurality of pattern forming parts 200 having the opening pattern are prepared, and then settled between the supporting frame 100 and the auxiliary supporting frame 300 (refer to FIG. 7B). Here, the supporting frame 100 and the auxiliary supporting frame 300 are made of metal and formed as a single body. Further, the circumference of the auxiliary supporting frame 300 may have a recessed part corresponding to the frame 400 or be provided with a supporting bar to support the frame 400.

Thus, the pattern forming part 200 welded to the individual frame 400 is coupled to the auxiliary supporting frame 300, thereby manufacturing the mask 1. In this case, there is no need to align the openings between the pattern forming parts 200 every time the pattern forming part 200 is formed. That is, the openings are aligned while the pattern forming part 200 is welded to the frame 400, so that an additional aligning process is not needed when the pattern forming part 200 is coupled with the supporting part 100 and the auxiliary supporting frame 300.

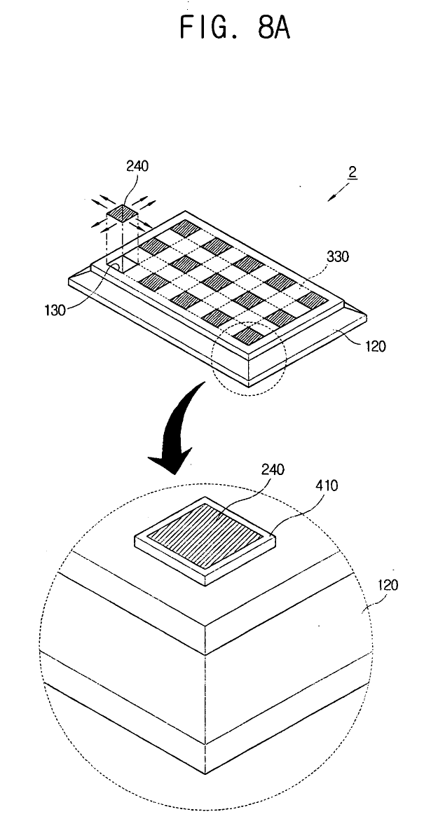

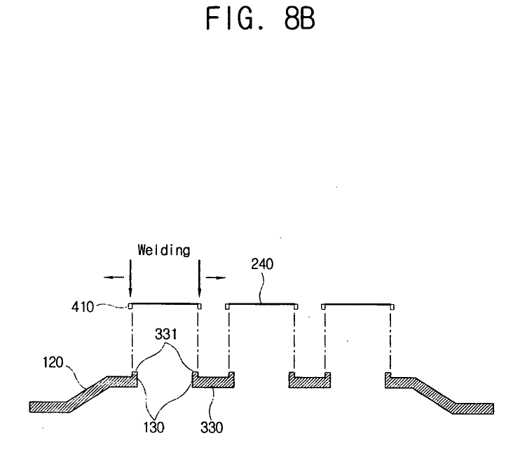

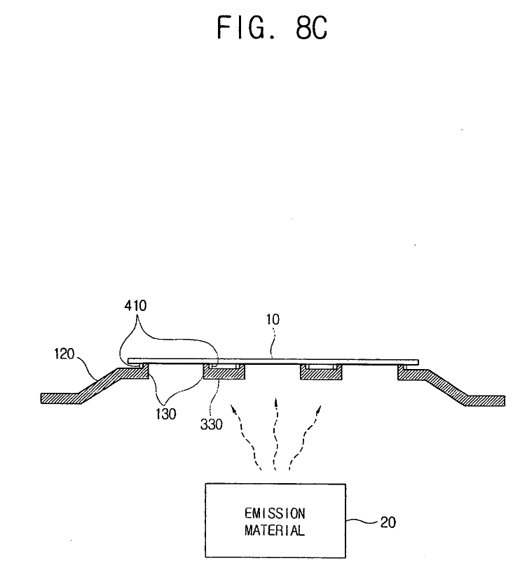

FIGS. 8A through 8C shows a method of manufacturing a display device according to a seventh embodiment of the present invention. FIG. 8A is a schematic view of a mask 2 according to the present embodiment; FIG. 8B illustrates a process of welding a pattern forming unit to the auxiliary supporting frame; and FIG. 8C illustrates a process of forming an emission layer on the substrate 10 by using the mask 2 according to this embodiment.

As shown in FIG. 8A, a supporting frame 120 and an auxiliary supporting frame 330 are formed as a single body, and an opening 130 is provided in a part corresponding to the pattern forming part 240.

A holder 410 is provided in the circumference of the pattern forming part 240, supports the pattern forming part 240, and fastens the pattern forming part 240 to the auxiliary supporting frame 330 while being welded. Here, the holder 410 and the pattern forming part 240 surrounded with the holder 410 are welded to the opening 130.

FIG. 8B is a sectional view of the mask 2. As shown in FIG. 8B, the auxiliary supporting frame 330 includes a projection 331 protruding upward in correspondence with the holder 410. That is, the holder 410 surrounds and is engaged with the projection 331, thereby being coupled to the projection 331.

Then, the pattern forming part 240 is welded where it is in contact with the projection 331. When the pattern forming part 240 is welded, the tension is applied to the pattern forming part 240 in four directions. Further, it is important to align the opening 130 of the pattern forming part 240 to be welded with the opening 130 of the previously welded pattern forming part 240.

FIG. 8C illustrates a process of forming an emission layer on the substrate 10 by using the completed mask 2. The substrate 10 includes a thin film transistor, a pixel electrode connected to the thin film transistor, and a partition wall dividing the pixel electrodes. As shown therein, the substrate 10 should closely contact the mask 2 so as to form the emission layer.

At this time, the mask 2 closely contacts the substrate 10 in the state that the openings 130 of the mask 2 are arranged to correspond to the pixel electrode.

Referring to FIG. 8C, the pattern forming part 240 protrudes with respect to the adjacent auxiliary supporting frame 330. Because the pattern forming part 240 is welded on the projection 331 of the auxiliary supporting frame 330, the auxiliary supporting frame 330 is relatively recessed as compared with the pattern forming part 240 and thus it does not contact the substrate. Therefore, even though the mask 2 moves, the auxiliary supporting frame 330 is not in contact with the substrate 10, thereby preventing the emission layer or the pixel electrode from being scratched or defective.

Meanwhile, an emission material 20 is provided under the mask 2, and the emission material 20 is deposited on the substrate 10 in an evaporated state.

According to the present invention, the size of the pattern forming part formed with the openings is changed so that the mask can be applied to a large-sized substrate in order to easily deposit a low molecule material.

As described above, the present invention provides a mask for a low molecule deposition of a display device, and a method of manufacturing the display device using the same.

Although a few embodiments of the present invention have been shown and described, it will be appreciated by those skilled in the art that changes may be made in these embodiments without departing from the spirit and scope of the invention.

What is claimed is:

1. A mask comprising:
a supporting frame formed with a pattern forming region;
a plurality of pattern forming parts formed in the pattern forming region; and
an auxiliary supporting frame formed between the pattern forming parts.

2. The mask according to claim 1, wherein the pattern forming parts are regularly arranged.

3. The mask according to claim 1, wherein each pattern forming part comprises a square shape.

4. The mask according to claim 3, wherein the pattern forming parts are spaced apart from each other by the length of one side of the square in four directions.

5. The mask according to claim 1, wherein each pattern forming part comprises a rectangle shape.

6. The mask according to claim 5, wherein the pattern forming parts are spaced apart from each other by the length of a long side of the rectangle in a long side direction of the pattern forming part and by the length of a short side of the rectangle in a short side direction at the pattern forming part.

7. The mask according to claim 1, wherein the pattern forming parts comprise a stripe shape, which are regularly spaced apart from each other.

8. The mask according to claim 7, wherein the stripe has the same width with a space between the pattern forming parts.

9. The mask according to claim 1, wherein the pattern forming parts comprise a plurality of openings adjacent to each other in one of a row direction and a column direction and spaced apart from each other by a predetermined distance in a the other direction.

10. The mask according to claim 1, wherein the pattern forming parts comprise openings that are randomly formed in an edge region thereof.

11. The mask according to claim 10, wherein the pattern forming parts comprise at least one pair of first and second opening patterns of which the openings are formed randomly and opposite to each other, and
the openings are arranged regularly when the first and second opening patterns are overlapped.

12. The mask according to claim 3, wherein the pattern forming parts comprise two pairs of opening patterns of which the openings are formed randomly and opposite to each other, and
the openings are arranged regularly when two pairs of opening patterns are overlapped.

13. The mask according to claim 12, wherein the pattern forming parts comprise four different corner opening patterns formed in the corners of the pattern forming parts and randomly formed with openings, and
the openings are arranged regularly when the plurality of corner opening patterns are overlapped.

14. The mask according to claim 5, wherein the pattern forming parts comprise two pairs of opening patterns of which the openings are formed randomly and opposite to each other, and
the openings are arranged regularly when two pairs of opening patterns are overlapped.

15. The mask according to claim 14, wherein the patterning forming parts comprise four different corner opening patterns formed in the corners of the pattern forming part and randomly formed with openings, and
the openings are arranged regularly when the plurality of corner opening patterns are overlapped.

16. The mask according to claim 7, wherein the pattern forming parts comprise a pair of opening patterns of which the openings are randomly formed and which are formed in an edge of the pattern forming part, and
the openings are arranged regularly when the pair of opening patterns are overlapped.

17. The mask according to claim 1, wherein the mask is interposed between an insulating substrate and an organic material, and allows the organic material to be deposited on a predetermined position of the insulating substrate.

18. The mask according to claim 1, wherein the pattern forming part protrudes with respect to the auxiliary supporting frame.

19. A mask comprising:
a supporting frame formed with a pattern forming region;
a plurality of pattern forming parts formed in the pattern forming region and comprising openings formed randomly; and
an auxiliary supporting frame formed between the pattern forming parts.

20. The mask according to claim 19, wherein the pattern forming part comprises at least one pair of first and second opening patterns which are opposite to each other, and
the openings are arranged regularly when the first and second opening patterns are overlapped.

21. A method of manufacturing a display device, comprising:
preparing a substrate comprising a thin film transistor and a pixel electrode connected to the thin film transistor;
attaching a mask to the substrate, the mask comprising a supporting frame formed with a pattern forming region, a plurality of pattern forming parts formed in the pattern forming region, and an auxiliary supporting frame formed between the pattern forming parts;
depositing an emission material on the pixel electrode corresponding to the pattern forming part;
moving the mask to dispose the pattern forming part on the pixel electrode corresponding to the auxiliary supporting frame;
forming an emission layer with the emission material by repeating the deposition of the emission material and the movement of the mask.

22. The method according to claim 21, further comprising manufacturing the mask.

23. The method according to claim 22, wherein the manufacture of the mask comprises:
forming the supporting frame and the auxiliary supporting frame as a single body;
preparing a plurality of pattern forming units comprising the pattern forming part and a holder supporting the circumference of the pattern forming part; and
welding the pattern forming unit to the auxiliary supporting frame while applying tension to the pattern forming part.

24. The method according to claim 23, wherein the auxiliary supporting frame comprises a projection protruding upward corresponding to the holder, and
the pattern forming unit is welded in the state that the holder is settled in the projection.

25. The method according to claim 22, wherein the manufacture of the mask comprises:
forming the supporting frame and the auxiliary supporting frame as a single body;
preparing a rectangular frame formed with an opening corresponding to the pattern forming part, and welding the pattern forming part to the frame while applying tension to the pattern forming part; and
coupling the frame with the supporting frame.

26. A mask comprising:
a supporting frame formed with a pattern forming region;
a plurality of pattern forming parts formed in the pattern forming region; and
an auxiliary supporting frame formed between the pattern forming parts and recessed with respect to the pattern forming part.

27. A mask comprising:
a supporting frame formed with a pattern forming region;
an auxiliary supporting frame formed in the pattern forming region; and
a pattern forming unit comprising a frame formed with an opening part, and a pattern forming part welded to the frame in correspondence with the opening part,
wherein the pattern forming unit is coupled to the auxiliary supporting frame and provided detachably from the supporting frame.
